(19) United States
(12) Patent Application Publication
(10) Pub. No.: US 2023/0247909 A1
(43) Pub. Date: Aug. 3, 2023

(54) ELECTRONIC DEVICE, ROBOT, AND MOVING STAGE

(71) Applicant: SEIKO EPSON CORPORATION, Tokyo (JP)

(72) Inventors: Mitsumi KISHIDA, SHIOJIRI-SHI (JP); Akiko KABUKI, SUWA-GUN FUJIMI-MACHI (JP)

(21) Appl. No.: 18/102,788

(22) Filed: Jan. 30, 2023

(30) Foreign Application Priority Data
Jan. 31, 2022 (JP) 2022-012895

(51) Int. Cl. H10N 30/87; H10N 30/20

(52) U.S. Cl. CPC H10N 30/875; H10N 30/206; B25J 19/0029

(57) ABSTRACT

An electronic device includes a first substrate having a terminal disposed on a first side surface, a second substrate stacked on the first substrate, a third substrate stacked on a opposite side of the second substrate from the first substrate, and a wiring substrate disposed to face the first side surface and joined to the first side surface via a first joining member, wherein a second side surface of the second substrate that faces the wiring substrate is located on an opposite side of the first side surface from the wiring substrate.

The present application is based on, and claims priority from JP Application Serial Number 2022-012895, filed Jan. 31, 2022, the disclosure of which is hereby incorporated by reference herein in its entirety.

### BACKGROUND

### 1. Technical Field

A present disclosure relates to an electronic device, a robot, and a moving stage.

### 2. Related Art

For example, the mounting structure described in JP-A-2021-145041 includes a flexible wiring board, a non-flexible component, a connecting section that connects the flexible wiring board and the non-flexible component, and a protective resin that seals the connecting section.

However, in the mounting structure of JP-A-2021-145041, when the flexible wiring board and the non-flexible component are joined to each other at the connecting section, there is a concern that capillary action might cause moisture to spread in the connecting section through narrow spaces between the flexible wiring board and the non-flexible component, and reduce reliability of mechanical and electrical connections.

### SUMMARY

An electronic device of the present disclosure includes a first substrate having a terminal disposed on a first side surface, a second substrate stacked on the first substrate, a third substrate stacked on a opposite side of the second substrate from the first substrate, and a wiring substrate disposed to face the first side surface and joined to the first side surface via a first joining member, wherein a second side surface of the second substrate that faces the wiring substrate is located on an opposite side of the first side surface from the wiring substrate.

A robot of the present disclosure includes a joint and an electronic device configured to drive the joint, wherein the electronic device including a first substrate having a terminal disposed on a first side surface, a second substrate stacked on the first substrate, a third substrate stacked on a opposite side of the second substrate from the first substrate, and a wiring substrate disposed to face the first side surface and joined to the first side surface via a first joining member and a second side surface of the second substrate that faces the wiring substrate is located on an opposite side of the first side surface from the wiring substrate.

A moving stage of the present disclosure includes a base, a movable section connected to the base, and an electronic device that moves the movable section relative to the base, wherein the electronic device including a first substrate having a terminal disposed on a first side surface, a second substrate stacked on the first substrate, a third substrate stacked on a opposite side of the second substrate from the first substrate, and a wiring substrate disposed to face the first side surface and joined to the first side surface via a first joining member and a second side surface of the second substrate that faces the wiring substrate is located on an opposite side of the first side surface from the wiring substrate.

### BRIEF DESCRIPTION OF THE DRAWINGS

FIG. 1 is a plan view showing a piezoelectric motor according to a first embodiment of the disclosure.

FIG. 2 is an exploded perspective view of a piezoelectric drive device.

FIG. 3 is a plan view of a piezoelectric actuator.

FIG. 4 is a sectional view taken along line A-A in FIG. 3.

FIG. 5 is a sectional view taken along line B-B in FIG. 3.

FIG. 6 is a sectional view taken along line C-C in FIG. 3.

FIG. 7 is a perspective view showing a first side surface of the piezoelectric actuator.

FIG. 8 is a cross-sectional view showing a joining state between the piezoelectric drive device and a wiring substrate.

FIG. 9 is a plan view showing the wiring substrate.

FIG. 10 is a cross-sectional view for explaining a method of joining the piezoelectric drive device and the wiring substrate.

FIG. 11 is a cross-sectional view for explaining the method of joining the piezoelectric drive device and the wiring substrate.

FIG. 12 is a cross-sectional view for explaining the method of joining the piezoelectric drive device and the wiring substrate.

FIG. 13 is a plan view showing a driving state of the piezoelectric actuator.

FIG. 14 is a plan view showing a driving state of the piezoelectric actuator.

FIG. 15 is a cross-sectional view showing an electronic device according to a second embodiment.

FIG. 16 is a cross-sectional view showing an electronic device according to a third embodiment.

FIG. 17 is a cross-sectional view showing an electronic device according, to a fourth embodiment.

FIG. 18 is a perspective view showing a robot according to a fifth embodiment.

FIG. 19 is a perspective view showing a moving stage according to a sixth embodiment.

### DESCRIPTION OF EMBODIMENT

Hereinafter, an electronic device, a robot, and a moving stage according to the disclosure will be described in detail based on preferred embodiments illustrated in the accompanying drawings.

### First Embodiment

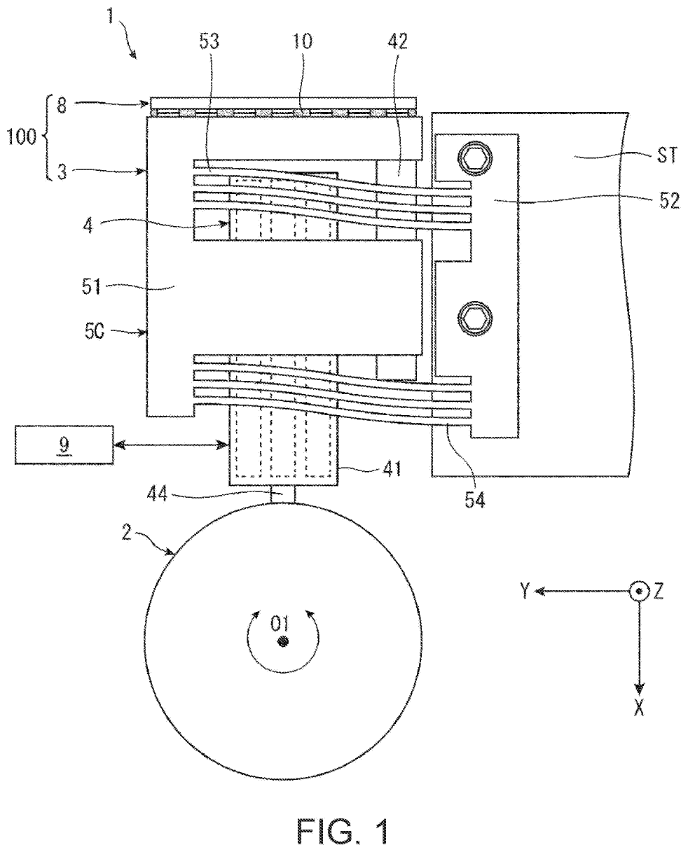

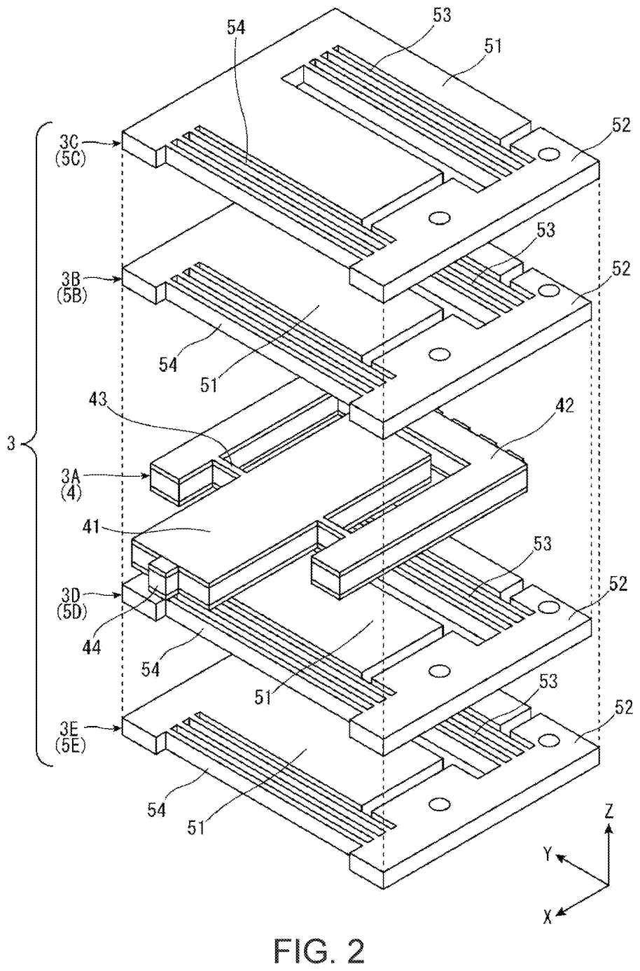

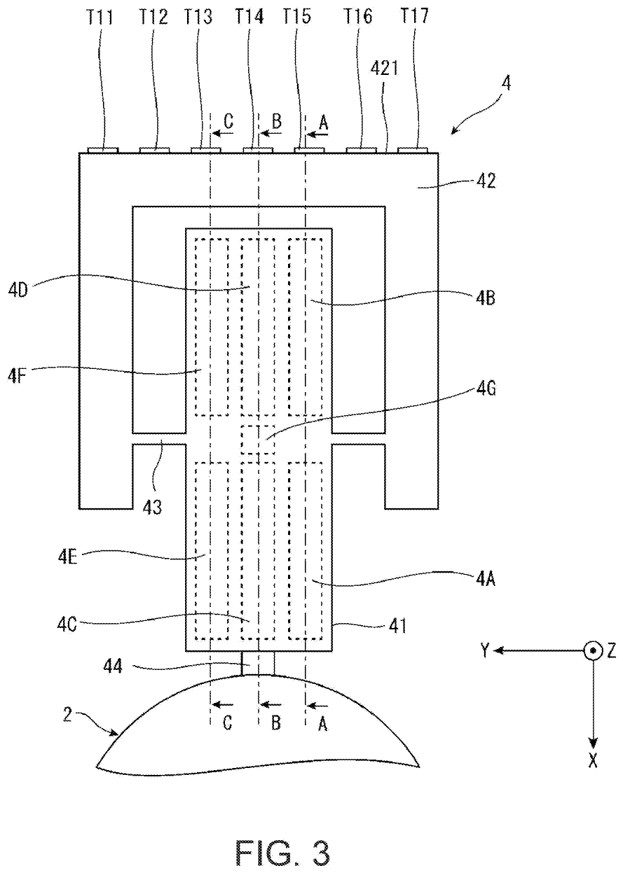

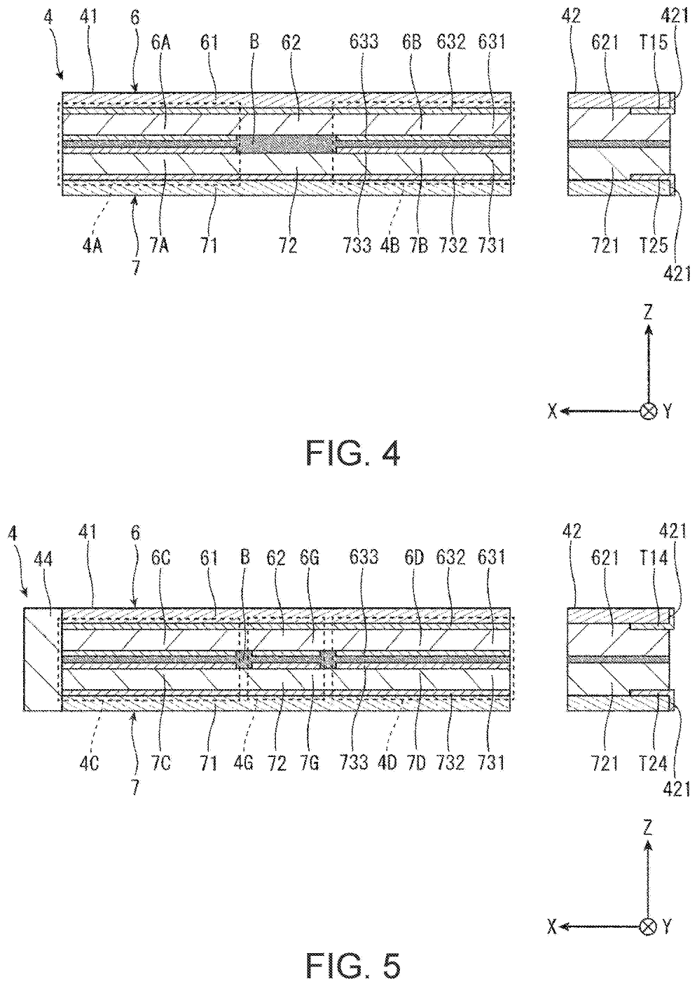

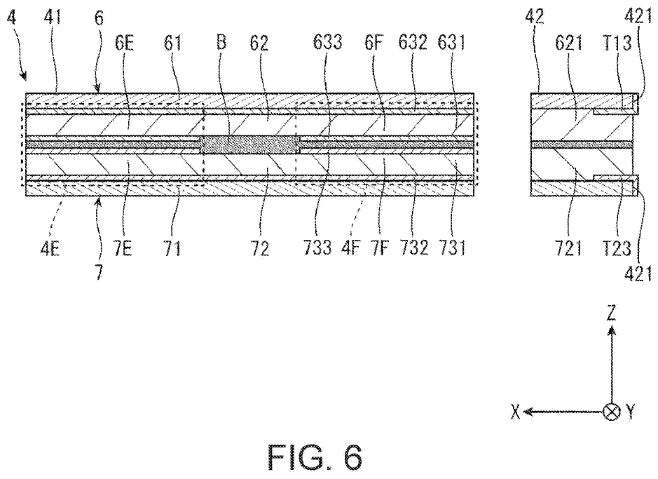

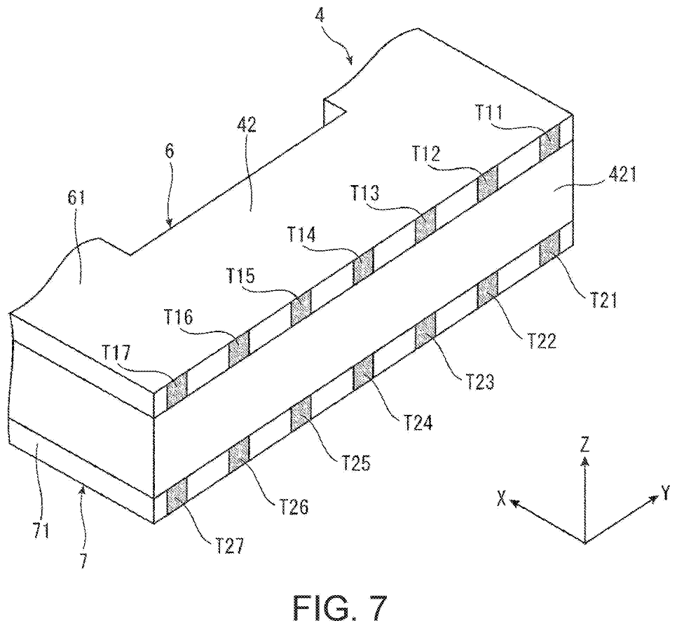

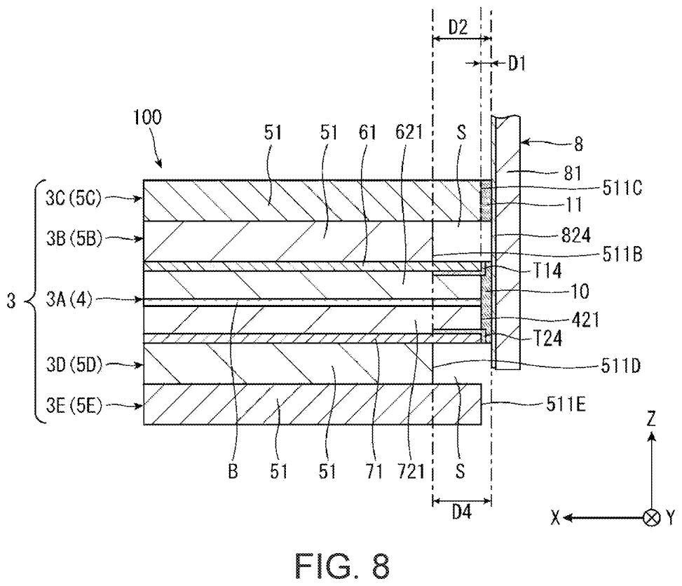

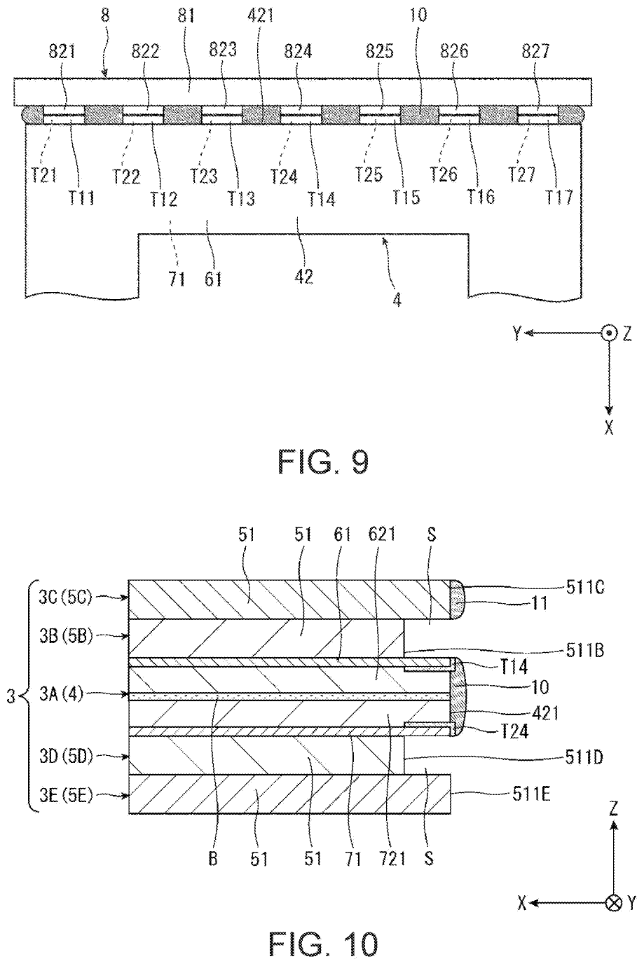

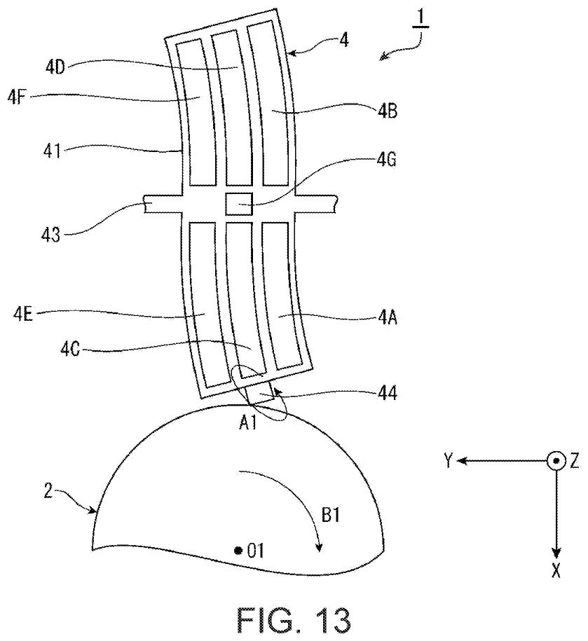

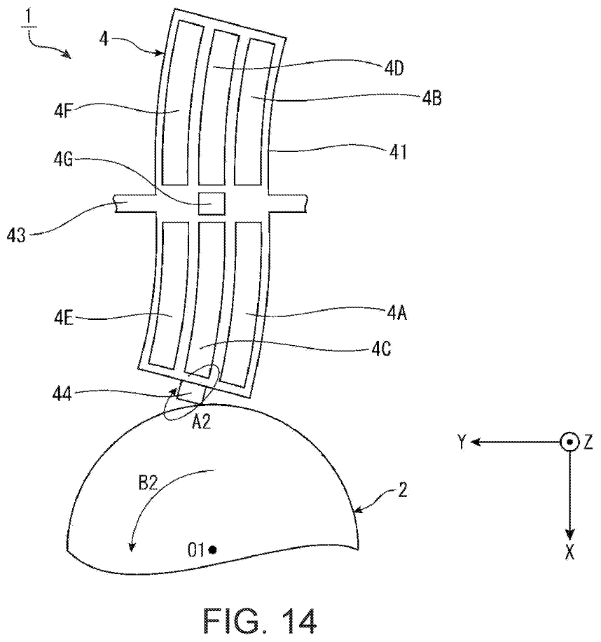

FIG. 1 is a plan view showing a piezoelectric motor according to a first embodiment of the disclosure. FIG. 2 is an exploded perspective view of a piezoelectric drive device. FIG. 3 is a plan view of a piezoelectric actuator. FIG. 4 is a sectional view taken along line A-A in FIG. 3. FIG. 5 is a sectional view taken along line B-B in FIG. 3. FIG. 6 is a sectional view taken along line C-C in FIG. 3. FIG. 7 is a perspective view showing a first side surface of the piezoelectric actuator. FIG. 8 is a cross-sectional view showing a joining state between the piezoelectric drive device and a wiring substrate. FIG. 9 is a plan view showing the wiring substrate. FIGS. 10 to 12 are cross-sectional views for explaining a method of joining a piezoelectric drive device and the wiring substrate. FIGS. 13 and 14 are plan views showing a driving state of the piezoelectric actuator.

Hereinafter, for convenience of description, a side of a piezoelectric actuator 4 toward a rotor 2 is also referred to as a “tip end side”, and a side opposite to the rotor 2 is also referred to as a “base end side”. In addition, three axes perpendicular to each other are referred to as an X-axis, a Y-axis, and a Z-axis, and a direction along the X-axis is referred to as an X-axis direction, a direction along the Y-axis is referred to as a Y-axis direction, and a direction along the Z-axis is referred to as a Z-axis direction. In addition, an arrow side of the axes is also referred to as a “plus side”, and a side opposite to the arrow is also referred to as a “minus side”.

A piezoelectric motor 1 illustrated in FIG. 1 includes the rotor 2, which is rotatable about a rotation axis O1, and an electronic device 100, which is a drive source that rotates the rotor 2. In addition, the electronic device 100 includes a piezoelectric drive device 3 that contacts an outer peripheral surface of the rotor 2, a wiring substrate 8 that is connected to the piezoelectric drive device 3, and a control device 9 that is electrically connected to the piezoelectric drive device 3 via the wiring substrate 8. In the piezoelectric motor 1, the piezoelectric drive device 3 is driven by control of the control device 9, and driving force generated by the piezoelectric drive device 3 is transmitted to the rotor 2, so that the rotor 2 rotates around the rotation axis O1. However, the configuration of the piezoelectric motor 1 is not particularly limited. For example, instead of the rotor 2, a linearly moving slider may be used.

As shown in FIG. 2, the piezoelectric drive device 3 is configured as a stacked body in which a first substrate 3A, a second substrate 3B, a third substrate 3C, a fourth substrate 3D, and a fifth substrate 3E are stacked in the Z-axis direction. To be more specific, the first substrate 3A is positioned at the center, the first substrate 3A is sandwiched by the second and fourth substrates 3B and 3D on either side, and the resulting stacked body is sandwiched by the third and fifth substrates 3C and 3E on either side. That is, the fifth substrate 3E, the fourth substrate 3D, the first substrate 3A, the second substrate 3B, and the third substrate 3C are stacked in this order from the minus side in the Z-axis direction. The substrates 3A to 5E are joined to each other via adhesive (not shown).

From among the substrates 3A to 3E, the first substrate 3A constitutes the piezoelectric actuator 4. The piezoelectric actuator 4 includes a vibration section 41, a support section 42 that supports the vibration section 41, a beam section 43 that connects the vibration section 41 and the support section 42, and a convex section 44 that is disposed at a tip end portion of the vibration section 41 and that transmits vibration of the vibration section 41 to the rotor 2.

As shown in FIG. 3, the vibration section 41 has a longitudinal shape with the X-axis direction as a longitudinal direction. The vibration section 41 has piezoelectric elements 4A to 4F for driving and a piezoelectric element 4G for detecting vibration of the vibration section 41. The piezoelectric elements 4C and 4D are disposed side by side in the X-axis direction at a central portion of the vibration section 41. Further, the piezoelectric elements 4A and 4B are disposed side by side in the X-axis direction on the minus side in the Y-axis direction of the piezoelectric elements 4C and 4D, and piezoelectric elements 4E and 4F disposed side by side in the X-axis direction on the plus side in the Y-axis direction of the piezoelectric elements 4C and 4D. The piezoelectric elements 4A to 4F expand and contract in the X-axis direction by energization. However, the number and arrangement of the piezoelectric elements for driving are not particularly limited as long as desired vibration can be excited in the vibration section 41.

The piezoelectric element 4G for detection is disposed between the piezoelectric elements 4C and 4D. The piezoelectric element 4G receives an external force corresponding to the vibration of the vibration section 41 and outputs a detection signal corresponding to the received external force. Therefore, the vibration state of the vibration section 41 can be detected based on the detection signal output from the piezoelectric element 4G. Note that the number and arrangement of the piezoelectric elements for detection are not particularly limited as long as the vibration of the vibration section 41 can be detected. The piezoelectric element for detection may be omitted.

The support section 42 has a U-shape surrounding the three sides of both sides and the base end side of the vibration section 41. In addition, the support section 42 is positioned at the base end of the piezoelectric actuator 4 and has a first side surface 421 facing the minus side of the X-axis direction. Further, the convex section 44 is provided at a tip end portion of the vibration section 41, and the tip end portion thereof is in contact with the outer peripheral surface of the rotor 2.

As shown in FIGS. 4 to 6, the piezoelectric actuator 4 is constructed by bonding two piezoelectric substrates 6 and 7 together. The piezoelectric substrate 6 has a first substrate 61 and a piezoelectric element layer 62 formed on a back surface of the first substrate 61. In addition, the piezoelectric element layer 62 has piezoelectric elements 6A to 6G disposed in the vibration section 41, and spacers 621 disposed in the support section 42 and the beam section 43. The piezoelectric elements 6A to 6G have a configuration in which a piezoelectric body 631 is sandwiched between a pair of electrodes 632 and 633. From among them, the electrode 632 and the piezoelectric body 631 are integrally formed across the piezoelectric elements 6A to 6G, respectively, and the electrode 633 is individually formed for each of the piezoelectric elements 6A to 6G.

Similarly, the piezoelectric substrate 7 has a second substrate 71 and a piezoelectric element layer 72 formed on a back surface of the second substrate 71. The piezoelectric element layer 72 has piezoelectric elements 7A to 7G disposed in the vibration section 41, and spacers 721 disposed in the support section 42 and the beam section 43. The piezoelectric elements 7A to 7G have a configuration in which a piezoelectric body 731 is sandwiched between a pair of electrodes 732 and 733. From among them, the electrode 732 and the piezoelectric body 731 are integrally formed across the piezoelectric elements 7A to 7G, respectively, and the electrode 733 is individually formed for each of the piezoelectric elements 7A to 7G.

The first and the second substrates 61 and 71 are not particularly limited, and for example, a silicon substrate can be used. As the constituent material of the piezoelectric body 631 and 731, for example, piezoelectric ceramics such as lead zirconate titanate (PZT), barium titanate, lead titanate, potassium niobate, lithium niobate, lithium tantalate, sodium tungstate, zinc oxide, barium strontium titanate (BST), strontium bismuth tantalate (SBT), lead metaniobate, and scandium lead niobate can be used.

The two piezoelectric substrates 6 and 7 described above are joined via adhesive B in a state in which the piezoelectric element layers 62 and 72 face each other. The piezoelectric element 4A is composed by two overlapping piezoelectric elements 6A and 7A, the piezoelectric element 4B is composed by two overlapping piezoelectric elements 6B and 7B, the piezoelectric element 4C is composed by two overlapping piezoelectric elements 6C and 7C, the piezoelectric element 4D is composed of two overlapping piezoelectric elements 6D and 7D, the piezoelectric element 4E is composed of two overlapping piezoelectric elements 6E and 7E, the piezoelectric element 4F is composed of two overlapping piezoelectric elements 6F and 7F, and the piezoelectric element 4G is composed of two overlapping piezoelectric elements 6G and 7G.

In addition, the thicknesses of the support section 42 and the beam section 43 are made equal to the thicknesses of the vibration section 41 by a stacked body including overlapping spacers 621 and 721. By this, deflection of the first and the second substrates 61 and 71 is suppressed.

As shown in FIG. 7, first terminals T11 T12, T13, T14, T15, T16, and T17 are disposed on the first side surface 421 of the first substrate 61. These seven first terminals T11 to T17 are disposed separated from each other in the Y-axis direction. The first terminal T11 is electrically connected to the electrode 633 of the piezoelectric element 6A via a wiring (not shown), the first terminal T12 is electrically connected to the electrode 633 of the piezoelectric element 6B via a wiring (not shown), the first terminal T13 is electrically connected to the electrodes 633 of the piezoelectric elements 6C and 6D via a wiring (not shown), the first terminal T14 is electrically connected to the electrode 633 of the piezoelectric element 6E via a wiring (not shown), the first terminal T15 is electrically connected to the electrode 633 of the piezoelectric element 6F via a wiring (not shown), the first terminal T16 is electrically connected to the electrode 633 of the piezoelectric element 6G via a wiring (not shown), and the first terminal T17 is electrically connected to the electrode 632 via a wiring (not shown). By this, the piezoelectric elements 6A to 6G can be connected to electrically via the first terminals T11 to T17.

Similarly, second terminals T21 T22, T23, T24, T25, T26, and 127 are disposed on the first side surface 421 of the second substrate 71. These seven second terminals T21 to T27 are disposed separated from each other in the Y-axis direction. The second terminal T21 is electrically connected to the electrode 733 of the piezoelectric element 7A via a wiring (not shown), the second terminal T22 is electrically connected to the electrode 733 of the piezoelectric element 7B via a wiring (not shown), the second terminal T23 is electrically connected to the electrodes 733 of the piezoelectric elements 7C and 7D via a wiring (not shown), the second terminal T24 is electrically connected to the electrode 733 of the piezoelectric element 7E via a wiring (not shown), the second terminal T25 is electrically connected to the electrode 733 of the piezoelectric element 7F via a wiring (not shown), the second terminal T26 is electrically connected to the electrode 733 of the piezoelectric element 7G via a wiring (not shown), and the second terminal T27 is electrically connected to the electrode 732 via a wiring (not shown). By this, the piezoelectric elements 7A to 7G can be connected to electrically via the second terminals T21 to T27.

In addition, the first terminal T11 and the second terminal T21, the first terminal T12 and the second terminal T22, the first terminal T13 and the second terminal T23, the first terminal T14 and the second terminal T24, the first terminal T15 and the second terminal T25, the first terminal T16 and the second terminal T26, and the first terminal T17 and the second terminal T27 are respectively arranged side by side in the Z-axis direction.

The first substrate 3A has been described above. Next, the second, third, fourth, and fifth substrates 3B, 3C, 3D, and 3E will be described. The second, third, fourth, and fifth substrates 3B, 3C, 3D, and 3E are biasing members 5B, 5C, 5D, and 5E that bias the piezoelectric actuator 4 toward the rotor 2 and press the convex section 44 against the outer peripheral surface of the rotor 2.

As shown in FIGS. 1 and 2, the biasing members 5B, 5C, 5D, and 5E include a holding section 51 that holds the support section 42 of the piezoelectric actuator 4, a base 52 that fixes the piezoelectric drive device 3 to the stage ST, and a pair of spring groups 53 and 54 that include a plurality of springs that connect the holding section 51 and the base 52. The biasing members 5B 5C, 5D, and 5E bias the piezoelectric actuator 4 toward the rotor 2 by using restoring force of the spring group 53 and 54. However, the configuration of the biasing members 5B, 5C, 5D, and 5E is not particularly limited as long as the piezoelectric actuators 4 can be biased toward the rotor 2.

In particular, as in the present embodiment, by sandwiching the piezoelectric actuator 4 from both sides between the biasing members 5B and 5C and the biasing members 5D and 5E, change in the posture of the piezoelectric actuator 4 about the X-axis is suppressed, and the piezoelectric actuator 4 can be biased toward the rotor 2 in a well-balanced manner. Therefore, driving force of the piezoelectric motor 1 can be efficiently transmitted to the rotor 2, and the driving of the piezoelectric motor 1 is stabilized. Furthermore, by arranging two biasing members 5B and 5C on one side of the piezoelectric actuator 4, an ideal biasing state can be easily achieved. For example, by combining biasing members 5B and 5C having spring constants different from each other, a change in biasing force with respect to a change in deflection amount of the spring group 53 and 54 can be suppressed to be small. Therefore, even if the amount of deflection of the spring groups 53 and 54 decreases due to wear of the convex section 44 over time, a sufficient biasing force can be maintained. Therefore, the piezoelectric motor 1 can be stably driven for a long time. The same applies to the biasing members 5D and 5E.

As shown in FIG. 8, the holding section 51 of the biasing member 5B disposed adjacent to the piezoelectric actuator 4 has a second side surface 511B opposed to the wiring substrate 8. The holding section 51 of the biasing member 5D, which is disposed adjacent to the piezoelectric actuator 4, has a fourth side surface 511D opposed to the wiring substrate 8. The second and fourth side surfaces 511B and 511D are located further toward the positive side in the X-axis direction than the first side surface 421 that is, toward a side opposite from that of the wiring substrate 8. Therefore, a separation distance D2 between the second and fourth side surfaces 511B and 511D and the wiring substrate 8 is larger than a separation distance D1 between the first side surface 421 and the wiring substrate 8. That is, D1<D2 and D1<D4.

The holding section 51 of the biasing member 5C, which is disposed adjacent to the biasing member 5B, has a third side surface 511C facing the wiring substrate 8. The holding section 51 of the biasing member 5E, which is disposed adjacent to the biasing member 5D, has a fifth side surface 511E facing the wiring substrate 8. The third and fifth side surfaces 511C and 511E are flush with the first side surface 421.

As shown in FIG. 9, the wiring substrate 8 is a printed wiring substrate having flexibility. This improves the degree of freedom in arrangement of the wiring substrate 8. The wiring substrate 8 has a substrate 81 and wirings 821, 822, 823, 824, 825, 826, and 827 disposed on the substrate 81. However, the wiring substrate 8 is not particularly limited, and may be a hard printed wiring substrate.

In addition, the wiring substrate 8 is disposed so that the surface on which the wirings 821 to 827 are disposed faces toward the first side surface 421 side and confronts the first side surface 421. The wiring substrate 8 is joined to the piezoelectric actuator 4 via a conductive first joining member 10 disposed between the wiring substrate 8 and the first side surface 421, and is electrically connected to the first terminals T11 to T17 and the second terminals T21 to T27.

To be more specific, the wiring 821 and first and second terminals T11 and T21, the wiring 822 and first and second terminals T12 and T22, the wiring 823 and first and second terminals T13 and T23, the wiring 824 and first and second terminals T14 and T24, the wiring 825 and first and second terminals T15 and T25, the wiring 826 and first and second terminals T16 and T26, and the wiring 827 and first and second terminals T17 and T27 are electrically connected. In this manner, by joining the wiring substrate 8 to the support section 42, it is possible to smoothly drive the piezoelectric actuator 4 without inhibiting vibration of the vibration section 41 by the wiring substrate 8. Further, vibration of the vibration section 41 is hardly transmitted to the first joining member 10, so that fatigue of the first joining member 10 can be reduced.

The first joining member 10 is a thermosetting adhesive. This facilitates joining between the wiring substrate 8 and the piezoelectric actuator 4. Further, the first joining member 10 has conductivity. As a result, mechanical joining and electrical connection can be performed simultaneously, and joining between the wiring substrate 8 and the piezoelectric actuator 4 becomes easier. In the present embodiment, an epoxy-based adhesive containing solder particles (reflow mounting anisotropic conductive paste) is used as the first joining member 10. By using such an adhesive, as will be described later, the wiring substrate 8 and the supporting section 42 can be mechanically and electrically connected more easily.

Furthermore, the wiring substrate 8 is joined to the biasing member 5C via a second joining member 11 disposed between the wiring substrate 8 and the third side surface 511C. Note that the second joining member 11 is not electrically connected to the wiring substrate 8. In this manner, by joining the piezoelectric drive device 3 and the wiring substrate 8 also by the second joining member 11 in addition to the first joining member 10, it is possible to further increase the joining strength between the piezoelectric drive device 3 and the wiring substrate 8. Furthermore, stress concentration on the first joining member 10 which is responsible for electrical connection is alleviated, and fatigue of the first joining member 10 can be reduced. Therefore, the reliability of the electronic device 100 can be improved.

The second joining member 11 is not accompanied by electrical connection between the piezoelectric drive device 3 and the wiring substrate 8. Therefore, any material may be used as long as a short circuit between the wirings 821 to 827 can be prevented. In this embodiment, the same material as that of the first joining member 10 is used. By this, it is possible to reduce the material cost, and it is possible to perform the application of the first and second joining members 10 and 11 in the same process, and thus it is possible to easily perform the joining between the piezoelectric drive device 3 and the wiring substrate 8.

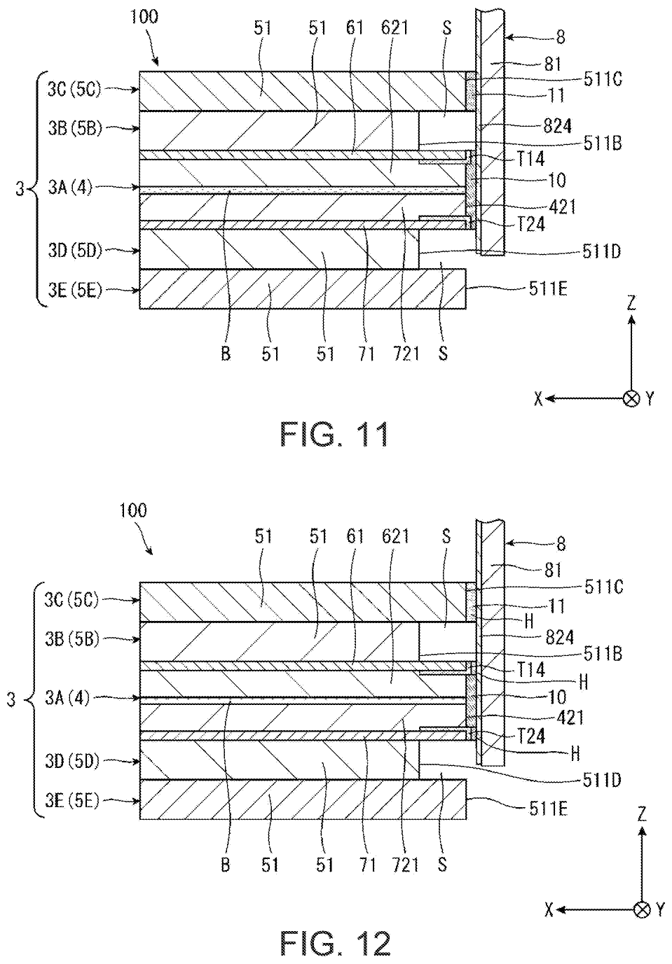

Next, a method of joining the piezoelectric drive device 3 and the wiring substrate 8 will be described. First, as shown in FIG. 10, the uncured first joining member 10 is applied to the first side surface 421 and the uncured second joining member 11 is applied to the third side surface 511C. Next, as shown in FIG. 11, the wiring substrate 8 is joined to the first side surface 421 and to the third side surface 511C. Next, the first and second joining members 10 and 11 are heated and cured to join the piezoelectric drive device 3 and the wiring substrate 8. When the first and second joining members 10 and 11 are heated, then as shown in FIG. 12, the solder particles H in the first and second joining members 10 and 11 self-aggregate to the first terminals T11 to T17, the second terminals T21 to T27, and the wirings 821 to 827 to form metallic bonds. Therefore, it is possible to electrically connect the terminals with the, corresponding wirings while preventing a short circuit between adjacent terminals. In this mariner, by using the epoxy-based adhesive containing solder particles (reflow mounting anisotropic conductive paste) as the first joining member 10, it is not necessary to individually apply the first joining member 10 for each terminal, and thus it is possible to easily perform joining between the piezoelectric drive device 3 and the wiring substrate 8.

Here, as described above, since a space S is formed on both sides of the first side surface 421 the development of the capillary action is suppressed, the uncured first joining member 10 is less likely to spread outward from the region between the first side surface 421 and the wiring substrate 8 when joining between the wiring substrate 8 and the piezoelectric drive device 3, and an appropriate amount of the first joining member 10 can be retained between the first side surface 421 and the wiring substrate 8. Therefore, it is possible to improve the reliability of mechanical and electrical connection between the piezoelectric drive device 3 and the wiring substrate 8.

Similarly, the uncured second joining member 11 is less likely to spread outward from the region between the third side surface 511C and the wiring substrate 8, and an appropriate amount of the second joining member 11 can be retained between the third side surface 511C and the wiring substrate 8. Therefore, the piezoelectric drive device 3 and the wiring substrate 8 can be more firmly joined to each other. In particular, in the present embodiment, the third side surface 511C is flush with the first side surface 421. By this, it is possible to reduce deflection of the wiring substrate 8 in a state of being joined to the piezoelectric drive device 3, and the load applied to the first joining member 10 and the second joining member 11 is reduced. Therefore, fatigue of the first and second joining members 10 and 11 can be reduced, and reliability of the electronic device 100 can be improved.

The separation distances D2 and D4 are not particularly limited, but are desirably, for example, 300 μm or more. As a result, the second and fourth side surfaces 511B and 511D are sufficiently spaced apart from the wiring substrate 8, and it is possible to more reliably suppress the spread of moisture in the first and second joining members 10 and 11. An upper limit value of the separation distances D2 and D4 is not particularly limited, but is desirably, for example, 500 μm, and is about 400 μm in the present embodiment. By this, an increase in the size of the piezoelectric drive device 3 due to an excessive increase in the separation distances D2, D4 can be suppressed.

The thickness of the biasing members 5B and 5D is not particularly limited, but is desirably, for example, 300 μm or more. By this, since the width (the length in the Z-axis direction) of the space S is ensured to be sufficiently large, it is possible to effectively suppress spread of moisture in the first and second joining members 10 and 11, which are on either side of the space S. Therefore, it is possible to more reliably suppress moisture from spreading in the first and second joining members 10 and 11. Note that an upper limit of the thickness is not particularly limited, but is desirably, for example, 500 μm, and is about 400 μm in the present embodiment. By this, it is possible to suppress an increase in size of the piezoelectric drive device 3 that could be caused by an excessive increase in thickness.

The control device 9 is constituted by, for example, a computer, and includes a processor that processes information, a memory that is communicably connected to the processor, and an external interface. In addition, the memory stores programs executable by the processor, and the processor reads and executes the programs stored in the memory. The control device 9 receives a command from a host computer (not shown) and drives the piezoelectric actuator 4 based on the command.

For example, when the phase differences of the alternating voltages applied to the piezoelectric elements 4A and 4F, the piezoelectric elements 4B and 4E, and the piezoelectric elements 4C and 4D are controlled so that, as shown in FIG. 13, the tip end of the convex section 44 makes an elliptical motion as indicated by arrow A1, then movement of the rotor 2 is started by this elliptical motion and the rotor 2 rotates clockwise as indicated by an arrow B1 Further, as shown in FIG. 14, when the tip end of the convex section 44 is caused to make an elliptical motion as indicated by an arrow A2, then movement of the rotor 2 is started by this elliptical motion and the rotor 2 rotates counterclockwise as indicated by an arrow B2,

The piezoelectric motor 1 of the present embodiment has been described above. The electronic device 100 included in the piezoelectric motor 1, as described above, includes the piezoelectric actuator 4, which is the first substrates 3A in which the first and second terminals T27 to T17 and T21 to 3A as terminals are disposed on the first side surface 421, the biasing member 5B, which is the second substrate 3B stacked on the piezoelectric actuator 4, the biasing member 5C, which is the third substrate 3C stacked on the opposite side of the biasing member 5B than the piezoelectric actuator 4, and the wiring substrate 8, which is disposed to face the first side surface 421 and is joined to the first side surface 421 via the first joining member 10. The second side surface 511B of the biasing member 5B that faces the wiring substrate 8 is located on an opposite side of the first side surface 421 from the wiring substrate 8. By this, since the space S is formed adjacent to the first side surface 421, the development of the capillary action is suppressed the uncured first joining member 10 is less likely to spread outward from the region between the first side surface 421 and the wiring substrate 8 when joining the wiring substrate 8 and the first side surface 421 together, and an appropriate amount of the first joining member 10 can be retained between the first side surface 421 and the wiring substrate 8. Therefore, it is possible to improve the reliability of mechanical and electrical connection between the piezoelectric drive device 3 and the wiring substrate 8.

As described above, the third side surface 511C of the biasing member 5C, which faces the wiring substrate 8, is joined to the wiring substrate 8 via the second joining member 11. By this, the piezoelectric drive device 3 and the wiring substrate 8 can be more firmly joined to each other. Therefore, the reliability of the electronic device 100 can be increased.

As described above, the third side surface 511C is flush with the first side surface 421. By this it is possible to reduce deflection of the wiring substrate 8 in a state of being joined to the piezoelectric drive device 3, and the load applied to the first joining member 10 and the second joining member 11 is reduced. Therefore, fatigue of the first and second joining members 10 and 11 can be reduced, and reliability of the electronic device 100 can be improved.

Further, as described above, the first joining member 10 is the thermosetting adhesive. This facilitates joining between the first side surface 421 and the wiring substrate 8.

In addition, as described above, the first substrate 3A includes the vibration section 41, which has the piezoelectric elements 4A to 4F and vibrates by expansion and contraction of the piezoelectric elements 4A to 4F caused by energization, the convex section 44, which is disposed in the vibration section 41, the support section 42, which has the first side surface 421 and supports the vibration section 41, and the beam section 43, which couples the vibration section 41 and the support section 42. At least one of the second substrate 3B or the third substrate 3C is biasing members 5B and 5C for biasing the convex section 44. By this, the electronic device 100 can be applied to the piezoelectric drive device 3. Therefore, the electronic device 100 can be used as a driving source of the piezoelectric motor 1 or the like, and versatility thereof is enhanced.

As described above, the wiring substrate 8 extends in the stacking direction of the first substrate 3A, the second substrate 3B, and the third substrate 3C. As a result, the third side surface 511C and the wiring substrate 8 can face each other, and the joining therebetween is facilitated.

### Second Embodiment

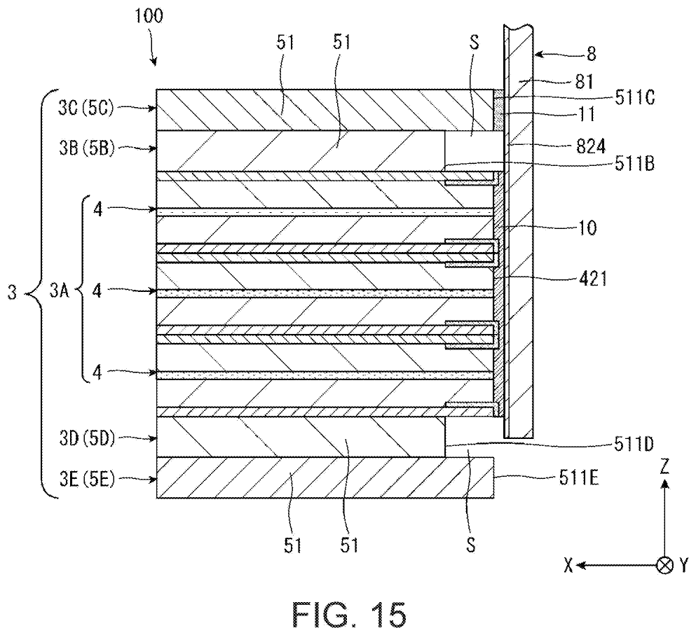

FIG. 15 is a cross-sectional view showing an electronic device according to a second embodiment.

The electronic device 100 of this embodiment is the same as the electronic device 100 of the first embodiment described above except that a plurality of piezoelectric actuators 4 are stacked. Therefore, in the following description, the present embodiment will be described with a focus on differences from the first embodiment described above, and description of similar matters will be omitted. In the drawings of the present embodiment, the same components as those of the above-described embodiment are denoted by the same reference symbols.

As shown in FIG. 15, in the, piezoelectric drive device 3 of the present embodiment, the first substrate 3A is constructed from a stack of a plurality of piezoelectric actuators 4. The plurality of piezoelectric actuators 4 are joined together via an adhesive (not shown). By stacking the plurality of piezoelectric actuators 4 in this manner, it is possible to increase driving force of the piezoelectric drive device 3. It should be noted that the number of stacked piezoelectric actuators 4 can be appropriately set according to the required driving force.

According to the second embodiment, the same effects as described for the first embodiment can be exhibited.

### Third Embodiment

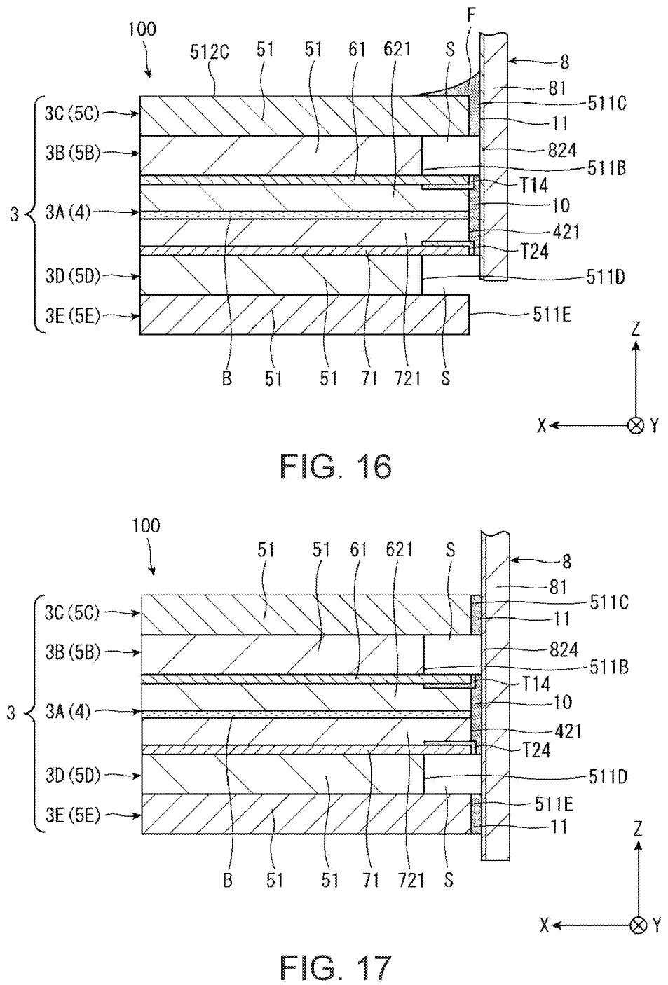

FIG. 16 is a cross-sectional view showing an electronic device according to a third embodiment.

The electronic device 100 of the present embodiment is the same as the electronic device 100 of the first embodiment described above except that the configuration of the second joining member 11 is different. Therefore, in the following description, the present embodiment will be described with a focus on differences from the first embodiment described above, and description of similar matters will be omitted. In the drawings of the present embodiment, the same components as those of the above-described embodiment are denoted by the same reference symbols.

As shown in FIG. 16, in the electronic device 100 of the present embodiment, the second joining member 11 is also disposed on an upper surface 512C, which is a main surface on an upper side of the holding section 51 of the biasing member 5C. By this, a fillet F is formed in the second joining member 11, and it is possible to further increase the joining strength between the piezoelectric drive device 3 and the wiring substrate 8. Therefore, the reliability of the electronic device 100 can be further enhanced.

As described above, in the electronic device 100 of the present embodiment, the second joining member 11 is also disposed on the upper surface 512C, which is the main surface of the third substrate 3C. By this, the fillet F is formed in the second joining member 11, and the joining, strength between the biasing member 5C and the wiring substrate 8 can be further increased. Therefore, the reliability of the electronic device 100 can be further enhanced.

According to the third embodiment as well, the same effects as those described above for the first embodiment can be achieved.

### Fourth Embodiment

FIG. 17 is a cross-sectional view showing an electronic device according to a fourth embodiment.

The electronic device 100 of the present embodiment is the same as the electronic device 100 of the first embodiment described above except that the fifth side surface 511E and the wiring substrate 8 are joined together. Therefore, in the following description, the present embodiment will be described with a focus on differences from the first embodiment described above, and description of similar matters will be omitted. In the drawings of the present embodiment, the same components as those of the above-described embodiment are denoted by the same reference symbols.

As shown in FIG. 17, in the electronic device 100 of the present embodiment, the fifth side surface 511E and the wiring substrate 8 are further joined together via the second joining member 11. As a result, the joining strength between the piezoelectric drive device 3 and the wiring substrate 8 can be further enhanced. Furthermore, stress concentration on the first joining member 10, which is responsible for electrical connection, is further alleviated, and fatigue of the first joining member 10 can be reduced. Therefore, the reliability of the electronic device 100 can be improved.

Particularly, in the present embodiment, the fifth side surface 511E is flush with the first side surface 421. By this, it is possible to reduce deflection of the wiring substrate 8 in the state of being joined to the piezoelectric drive device 3, and the load applied to the first joining member 10 and the second joining members 11 is reduced. Therefore, it is possible to reduce fatigue of the first and second joining members 10 and 11.

According to the fourth embodiment, the same effects as those of the first embodiment described above can be exerted.

### Fifth Embodiment

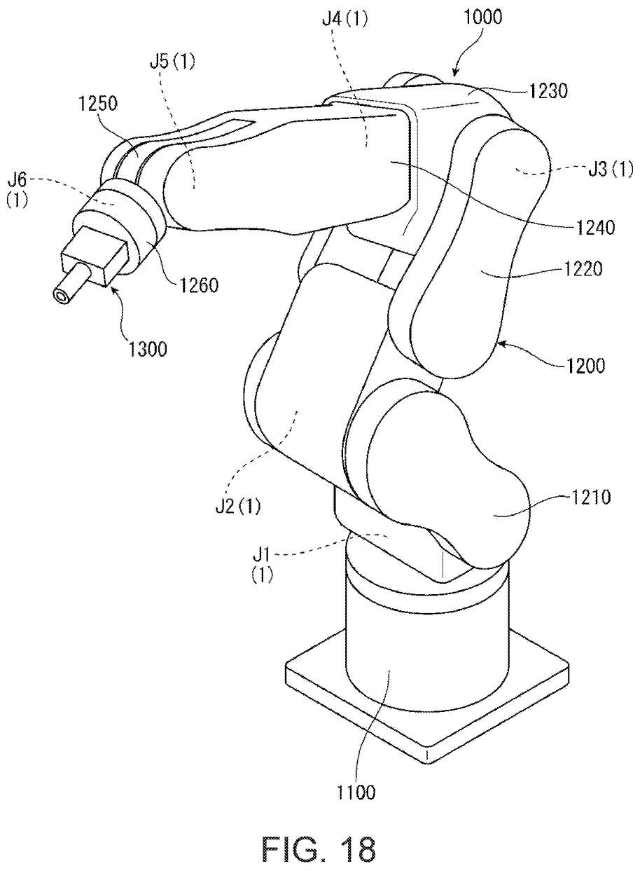

FIG. 18 is a perspective view showing a robot according to a fifth embodiment.

A robot 1000 illustrated in FIG. 18 can perform work such as material feeding, material removal, transport, and assembly of precision equipment and components constituting them. The robot 1000 is, for example, a robot that performs work such as material feeding, material removal, transport, and assembly of a precision equipment or components constituting them. However, the use of the robot 1000 is not particularly limited.

The robot 1000 is a six axes robot having six rotational axes. The robot 1000 includes a base 1100 and a robot arm 1200 rotatably coupled to the base 1100, and an end effector 1300 is attached to a tip end portion of the robot arm 1200.

Further, the robot arm 1200 is a robotic arm to which a plurality of arms 1210, 1220, 1230, 1240, 1250, and 1260 are rotatably coupled, and includes six joints J1 to J6. Among them, the joints J2, J3, and J5 are bending joints, and the joints J1, J4, and J6 are torsional joints. Further, an electronic device 100 as a drive source is installed in the joints J1, J2, J3 J4, J5, and J6. Therefore, the robot 1000 can enjoy the effects of the electronic device 100 and can exhibit excellent reliability.

However, the robot 1000 is not particularly limited, and may have at least one joint. In addition, the piezoelectric motor 1 may be disposed in at least one of the joints J1, J2, J3, J4, J5, and J6.

The robot 1000 has been described above. As described above, the robot 1000 includes the joints J1, J2, J3, J4, J5, and J6 and the electronic device 100 for driving the joints J1, J2, J3, J4, J5, and J6. The electronic device 100 includes the piezoelectric actuator 4, which is a first substrate 3A in which first and second terminals T11 to T17 and T21 to T27 as terminals are disposed on a first side surface 421, the biasing member 5B, which is the second substrate 3B stacked on the piezoelectric actuator 4, the biasing member 5C, which is the third substrate 3C stacked on the opposite side of the biasing member 5B than the piezoelectric actuator 4, and the wiring substrate 8, which is disposed to face the first side surface 421 and is joined to the first side surface 421 via the first joining member 10. The second side surface 511B of the biasing member 5B that faces the wiring substrate 8 is located on an opposite side of the first side surface 421 from the wiring substrate 8. By this, since the space S is formed adjacent to the first side surface 421, the development of the capillary action is suppressed, the uncured first joining member 10 is less likely to spread outward from the region between the first side surface 421 and the wiring substrate 8 when joining the wiring substrate 8 and the first side surface 421 together, and an appropriate amount of the first joining member 10 can be retained between the first side surface 421 and the wiring substrate 8. Therefore, it is possible to improve the reliability of mechanical and electrical connection between the piezoelectric drive device 3 and the wiring substrate 8. The robot 1000 using such the electronic device 100 can exhibit excellent reliability.

### Sixth Embodiment

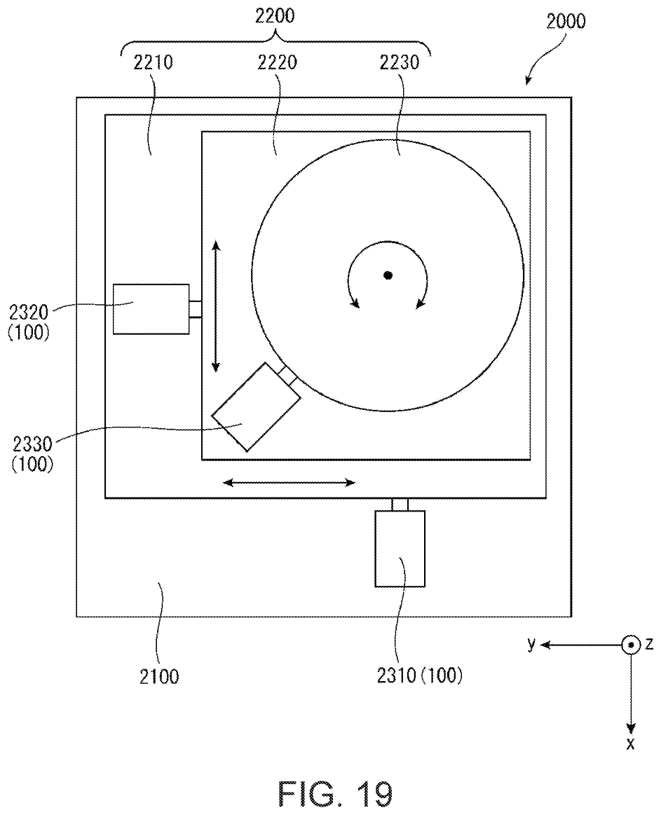

FIG. 19 is a perspective view showing a moving stage according to a sixth embodiment.

Hereinafter, for convenience of description, three axes perpendicular to each other are referred to as an x-axis, a y-axis, and a z-axis, and a direction along the x-axis is referred to as an x-axis direction, a direction along, the y-axis is referred to as a y-axis direction, and a direction along the z-axis is referred to as a z-axis direction.

The moving stage 2000 shown in FIG. 19 includes a base 2100 and a movable section 2200 that moves relative to the base 2100. The movable section 2200 includes a first movable section 2210 that moves in the y-axis direction with respect to the base 2100, a second movable section 2220 that moves in the x-axis direction with respect to the first movable section 2210, and a third movable section 2230 that moves around the z-axis with respect to the second movable section 2220.

The moving stage 2000 has a first drive source 2310 for moving the first movable section 2210 with respect to the base 2100, a second drive source 2320 for moving the second movable section 2220 with respect to the first movable section 2210, and a third drive source 2330 for moving the third movable section 2230 with respect to the second movable section 2220. The electronic device 100 is used as the first, second and third drive sources 2310, 2320, and 2330. Therefore, the moving stage 2000 can enjoy the effects of the electronic device 100 and can exhibit excellent reliability.

However, the moving stage 2000 is not particularly limited. For example, one or two of the first, second, and third movable sections 2210, 2220, and 2230 may be omitted. In addition, it is not necessary to use the electronic device 100 for all of the first, second, and third drive sources 2310, 2320, and 2330 and it is sufficient to use the electronic device 100 for at least one of them.

The moving stage 2000 has-been described above. As described above, such a moving stage 2000 includes the base 2100, the movable section 2200 connected to the base 2100, and the electronic device 100 for moving the movable section 2200 relative to the base 2100. The electronic device 100 includes the piezoelectric actuator 4, which is a first substrate 3A in which first and second terminals T11 to T17 and T21 to T27 as terminals are disposed on a first side surface 421, the biasing member 56, which is the second substrate 3B stacked on the piezoelectric actuator 4, the biasing member 5C, which is the third substrate 3C stacked on the opposite side of the biasing member 5B than the piezoelectric actuator 4, and the wiring substrate 8, which is disposed to face the first side surface 421 and is joined to the first side surface 421 via the first joining member 10. The second side surface 511B of the biasing member 5B that faces the wiring substrate 8 is located on an opposite side of the first side surface 421 from the wiring substrate 8. By this, since the space S is formed adjacent to the first side surface 421, the uncured first joining member 10 is less likely to spread outward from the region between the first side surface 421 and the wiring substrate 8 when joining the wiring substrate 8 and the first side surface 421, and an appropriate amount of the first joining member 10 can be retained between the first side surface 421 and the wiring substrate 8. Therefore, it is possible to improve the reliability of mechanical and electrical connection between the piezoelectric drive device 3 and the wiring substrate 8. The moving stage 2000 using such the electronic device 100 can exhibit excellent reliability.

Although the electronic device, the robot, and the moving stage according to the disclosure have been described above based on the illustrated embodiments, the disclosure is not limited thereto, and the configuration of each section can be replaced with an arbitrary configuration having the same function. In addition, other arbitrary components may be added to the present disclosure. Further, the respective embodiments may be appropriately combined. In addition, in the embodiment described above, the configuration in which the electronic device 100 is applied to the piezoelectric motor 1, the robot 1000, and the moving stage 2000 has been described, but the electronic device 100 can also be applied to various devices other than these, for example, a printer, a projector, and the like.

What is claimed is:

1. An electronic device comprising:
a first substrate having a terminal disposed on a first side surface;
a second substrate stacked on the first substrate;
a third substrate stacked on a opposite side of the second substrate from the first substrate; and
a wiring substrate disposed to face the first side surface and joined to the first side surface via a first joining member, wherein
a second side surface of the second substrate that faces the wiring substrate is located on an opposite side of the first side surface from the wiring substrate.

2. The electronic device according to claim 1, wherein
a third side surface of the third substrate that faces the wiring substrate is joined to the wiring substrate via a second joining member.

3. The electronic device according to claim 2, wherein
the second joining member is also disposed on a main surface of the third substrate.

4. The electronic device according to claim 2, wherein
the third side surface is flush with the first side surface.

5. The electronic device according to claim 1, wherein
the first joining member is a thermosetting adhesive.

6. The electronic device according to claim 1, wherein
the first substrate includes a vibration section that includes a piezoelectric element and that is configured to vibrate by expansion and contraction of the piezoelectric element by energization, a convex section disposed on the vibration section, a support section that includes the first side surface and that is configured to support the vibration section, and a beam section configured to couple the vibration section and the support section and
at least one of the second substrate or the third substrate is a biasing member configured to bias the convex section.

7. The electronic device the according to claim 1, wherein
the wiring substrate extends in a direction in which the first substrate, the second substrate, and the third substrate are stacked.

8. A robot comprising:
a joint and
an electronic device configured to drive the joint, wherein
the electronic device including
a first substrate having a terminal disposed on a first side surface,
a second substrate stacked on the first substrate,
a third substrate stacked on a opposite side of the second substrate from the first substrate, and
a wiring substrate disposed to face the first side surface and joined to the first side surface via a first joining member and
a second side surface of the second substrate that faces the wiring substrate is located on an opposite side of the first side surface from the wiring substrate.

9. A moving stage comprising:
a base;
a movable section connected to the base; and
an electronic device that moves the movable section relative to the base, wherein
the electronic device including
a first substrate having a terminal disposed on a first side surface,
a second substrate stacked on the first substrate,
a third substrate stacked on a opposite side of the second substrate from the first substrate, and
a wiring substrate disposed to face the first side surface and joined to the first side surface via a first joining member and
a second side surface of the second substrate that faces the wiring substrate is located on an opposite side of the first side surface from the wiring substrate.
